(19) United States
(12) Patent Application Publication
(10) Pub. No.: US 2017/0084963 A1
(43) Pub. Date: Mar. 23, 2017

(54) BATTERY MODULE HAVING BIPOLAR CELL

(71) Applicant: Hyundai Motor Company, Seoul (KR)

(72) Inventor: Sang Mok Park, Seongnam-si (KR)

(73) Assignee: Hyundai Motor Company, Seoul (KR)

(21) Appl. No.: 14/952,473

(22) Filed: Nov. 25, 2015

(30) Foreign Application Priority Data
Sep. 21, 2015 (KR) 10-2015-0133293

(51) Int. Cl. H01M 10/48; H01M 10/04; G01R 31/36; H01M 2/08; H01M 2/02; H01M 10/0525; H01M 10/42

(52) U.S. Cl. CPC H01M 10/48; H01M 10/0525; H01M 10/0418; H01M 10/425; H01M 2/08; H01M 2/0237; G01R 31/362; G01R 31/3696; H01M 2220/20

(57) ABSTRACT

A battery module having a bipolar cell includes a plurality of anode plates and cathode plates alternately stacked and connected to each other in series. The anode plates have anode terminals and measuring terminals for measuring a voltage, and the respective cathode plates have cathode terminals and measuring terminals for measuring a voltage, such that steps are formed in the anode terminals, cathode terminals, and measuring terminals. A voltage monitoring terminal part also has steps formed in terminal connecting parts to correspond to the measuring terminals, allowing the measuring terminals to be inserted therein for measuring a voltage of the bipolar cell. The voltage of the bipolar cell is measured in a process to improve defect sorting performance to more easily detect an abnormal cell, thereby making it possible to improve marketability, durability and safety of the battery.

### CROSS-REFERENCE TO RELATED APPLICATIONS

This application claims the benefit of Korean Patent Application No. 10-2015-0133293, filed on Sep. 21, 2015, the contents of which are incorporated herein by reference in its entirety.

### FIELD

The present disclosure relates to a battery module having a bipolar cell.

### BACKGROUND

The statements in this section merely provide background information related to the present disclosure and may not constitute prior art.

Generally, a lithium secondary battery that is rechargeable and light and has high energy density and output density has been widely used as an energy source of a wireless mobile device.

In addition, a hybrid electric vehicle (HEV), a plug-in hybrid electric vehicle (PHEV), a battery electric vehicle (BEV), an electric vehicle (EV), or the like, have been suggested as a scheme for solving problems such as air pollution and greenhouse gas generated in an existing internal combustion engine vehicle using a fossil fuel, such as a gasoline vehicle, a diesel vehicle, or the like, and the lithium secondary battery has been prominent as a power source of a vehicle substituting for the internal combustion engine vehicle.

Meanwhile, recently, an interest in a bipolar cell has increased in accordance with the development of a solid electrolyte. A bipolar cell technology, which is a technology capable of manufacturing a high voltage battery cell by connecting bicells to each other in series within the bipolar cell, has been evaluated as an important technology that may produce innovation in a pack structure, and the like, as well as improvement of battery energy density.

Currently, a defect of a lithium ion battery cell due to an internal short-circuit, or the like, generated in a process of manufacturing the lithium ion battery cell has been sorted using a statistical method of checking a variation in a voltage during a predetermined period after the lithium ion battery cell is charged.

### SUMMARY

The present disclosure has been made to solve the above-mentioned problems occurring in the prior art while advantages achieved by the prior art are maintained intact.

The present disclosure provides a battery module having a bipolar cell capable of easily sorting a defect of the bipolar cell at the time of manufacturing the bipolar cell and improving durability and safety of a battery by measuring a voltage of the bipolar cell.

According to one form of the present disclosure, a battery module having a bipolar cell includes: a bipolar cell including a plurality of anode plates and cathode plates alternately stacked and connected to each other in series, the respective anode plates having anode terminals formed at one ends thereof and having measuring terminals formed at the other ends thereof and measuring a voltage and the respective cathode plates having cathode terminals formed at one ends thereof and having measuring terminals formed at the other ends thereof and measuring a voltage, such that steps are formed in a plurality of anode terminals, cathode terminals, and measuring terminals; and a voltage monitoring terminal part having steps formed in a plurality of terminal connecting parts so as to correspond to the measuring terminals to allow the measuring terminals to be inserted therein, thereby measuring a voltage of the bipolar cell.

The steps of the measuring terminals and the steps of the terminal connecting parts may have a stair shape in which the steps become high toward one end.

The voltage monitoring terminal part may include: a coupled part having the terminal connecting parts formed therein to have the measuring terminals inserted therein; a sealing part connected to the coupled part, provided with a flexible printed circuit board (PCB), and sealing the flexible PCB from an external environment, and a connector having one end connected to the flexible PCB of the sealing part and the other end at which a coupling terminal is formed to measure the voltage of the bipolar cell or sort a defect of the bipolar cell at the time of being coupled to a battery management system (BMS).

The battery module having a bipolar cell may further include a case type pouch provided at an outer side of the bipolar cell and having one end allowing the anode terminal and the cathode terminal to be exposed to the outside and the other end allowing a portion of the sealing part and the connector of the voltage monitoring terminal part to be exposed to the outside.

The sealing part may include: an outer layer heat-fused to the pouch; an intermediate layer formed at an inner side of the outer layer to maintain a shape of the sealing part and inhibit an electrical short-circuit at the time of heat-fusion to the pouch; and an inner layer formed at an inner side of the intermediate layer and connected to the flexible PCB to thereby be fused.

The coupled part in which the terminal connecting parts are formed may be coupled to the measuring terminals of the bipolar cell through welding, soldering, or riveting.

The outer layer and the inner layer may be melted and fused at a low melting point between 130° C. and 140° C., and the intermediate layer may be melted and fused at a high melting point between 164° C. and 166° C.

The sealing part may be made of polyethylene (PE) or polyimide (PI) and the flexible PCB formed in the sealing part may be made of copper (Cu), nickel (Ni), or aluminum (Al).

According to another form of the present disclosure, a battery module having a bipolar cell includes: a bipolar cell including a plurality of anode plates and cathode plates alternately stacked and connected to each other in series, the respective anode plates having anode terminals formed at one ends thereof and having measuring terminals formed at the other ends thereof and measuring a voltage and the respective cathode plates having cathode terminals formed at one ends thereof and having measuring terminals formed at the other ends thereof and measuring a voltage, such that stair-shaped steps are formed in a plurality of anode terminals, cathode terminals, and measuring terminals; a voltage monitoring terminal part including a coupled part having stair-shaped steps formed in a plurality of terminal connecting parts so as to correspond to the measuring terminals to have the measuring terminals inserted therein, a sealing part connected to the coupled part, provided with a flexible PCB, and sealing the flexible PCB from an external environment, and a connector having one end connected to the flexible PCB of the sealing part and the other end at which a coupling terminal is formed to measure a voltage of the bipolar cell or sort a defect of the bipolar cell at the time of being coupled to a BMS; and a case type pouch provided at an outer side of the bipolar cell and having one end allowing the anode terminal and the cathode terminal to be exposed to the outside and the other end allowing a portion of the sealing part and the connector of the voltage monitoring terminal part to be exposed to the outside.

The sealing part may include: an outer layer heat-fused to the pouch; an intermediate layer formed at an inner side of the outer layer to maintain a shape of the sealing part and inhibit an electrical short-circuit at the time of heat-fusion to the pouch; and an inner layer formed at an inner side of the intermediate layer and connected to the flexible PCB to thereby be fused.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a view illustrating a bipolar cell in a battery module having a bipolar cell according to one form of the present disclosure;

FIG. 2 is a cross-sectional view illustrating the battery module having a bipolar cell according to one form of the present disclosure;

FIG. 3 is a cross-sectional view illustrating a sealing part of the battery module having a bipolar cell according to one form of the present disclosure;

FIG. 4 is a cross-sectional view taken along line A-A′ of FIG. 3;

FIG. 5 is a cross-sectional view taken along line B-B′ of FIG. 3;

FIG. 6 is a cross-sectional view illustrating an example of the battery module having a bipolar cell according to one form of the present disclosure; and

FIG. 7 is a cross-sectional view taken along line C-C′ of FIG. 6.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

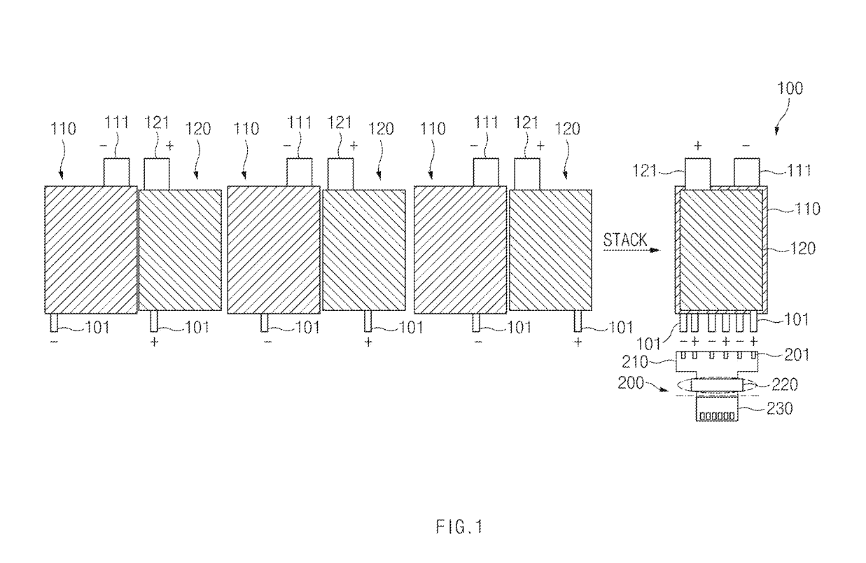

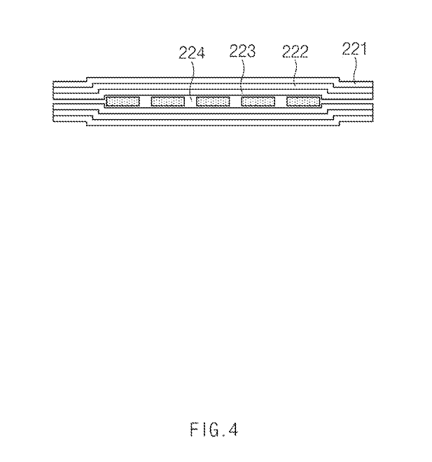

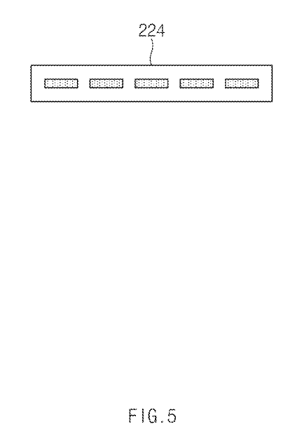

A battery module having a bipolar cell according to one form of the present disclosure is configured to include a bipolar cell 100 in which a plurality of anode plates 110 and cathode plates 120 are stacked, such that steps are formed in each of a plurality of anode terminals 111, cathodes terminals 121, and measuring terminals 101; and a voltage monitoring terminal part inserted into the measuring terminals 101 in which the steps are formed to measure a voltage of the bipolar cell 100, as illustrated in FIGS. 1 to 7.

As illustrated in FIG. 1, the bipolar cell 100 includes the plurality of anode plates 110 and cathode plates 120 alternately stacked and connected to each other in series.

The respective anode plates 110 have the anode terminals 111 formed at one ends thereof and have the measuring terminals 101 formed at the other ends thereof and measuring the voltage, and the respective cathode plates 120 have the cathode terminals 121 formed at one ends thereof and have the measuring terminals 101 formed at the other ends thereof and measuring the voltage.

Here, the respective anode terminals 111 are disposed in a state in which they are stacked at the left or the right of one ends of the anode plates 110, and the respective cathode terminals 121 are disposed in a state in which they are stacked in an opposite side to that of the anode terminals 111, that is, the right or the left of one ends of the cathode plates 120.

In addition, the steps are formed in the respective measuring terminals 101 formed at the other ends of the anode plates 110 and the cathode plates 120.

That is, the bipolar cell 100 is formed by stacking the anode plates 110 and the cathode plates 120 having opposite polarities, and the anode terminals 111 and the cathode terminals 121 are stacked at both sides of one side of the bipolar cell 100 and the respective measuring terminals 101 are formed at the other end of the bipolar cell 100 so as to have the step therebetween, such that mutual interference is not generated.

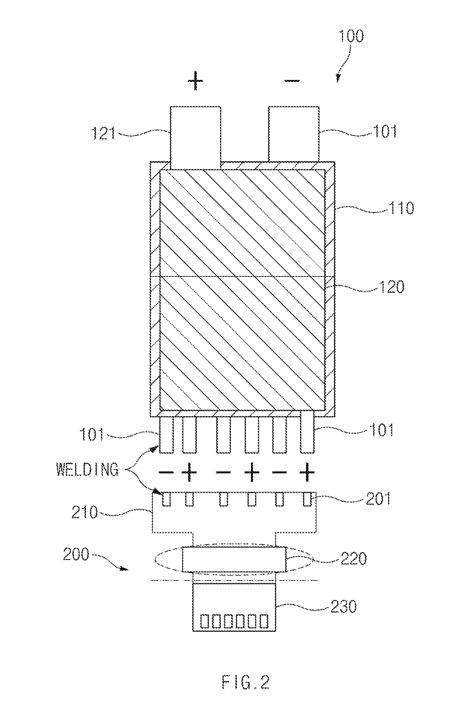

As illustrated in FIG. 2, the voltage monitoring terminal part has steps formed in a plurality of terminal connecting parts 201 so as to correspond to the measuring terminals 101 of the bipolar cell 100 to allow the measuring terminals 101 of the bipolar cell 100 to be connected to the terminal connecting parts 201.

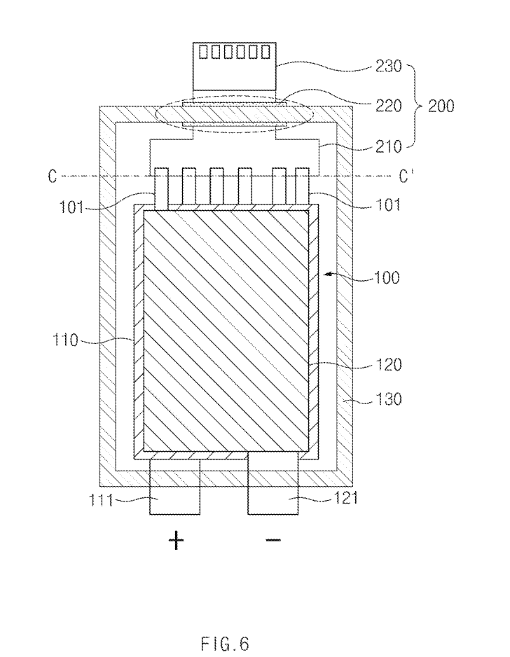

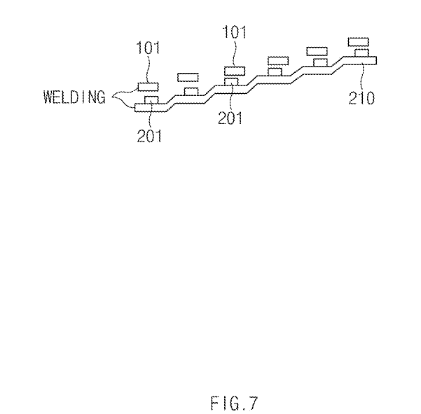

Here, as illustrated in FIGS. 6 and 7, the steps of the measuring terminals 101 and the steps of the terminal connecting parts 201 have a stair shape in which they become high toward one end, thereby making it possible to improve coupling force between the bipolar cell 100 and the voltage monitoring terminal part, inhibit generation of interference, and allow voltages of the bipolar cell 100 to be individually measured.

In addition, the voltage monitoring terminal part includes a coupled part 201 connected to the measuring terminals 101, a sealing part 220 provided with a flexible printed circuit board (PCB) 224, and a connector 230 measuring the voltage.

The coupled part 210 is provided with the terminal connecting parts 201 in which the stair-shaped steps are formed and is connected to the measuring terminals 101.

In one form the coupled part 210 in which the terminal connecting parts 201 are formed is coupled to the measuring terminals 101 of the bipolar cell 100 through welding, soldering, riveting, or the like.

The sealing part 220 is connected to the coupled part 210, is provided with the flexible PCB 224, and seals the flexible PCB 224 from an external environment.

The connector 230 has one end connected to the flexible PCB 224 of the sealing part 220 and the other end at which a coupling terminal is formed to measure the voltage of the bipolar cell 100 or sort a defect of the bipolar cell 100 at the time of being coupled to a battery management system (BMS).

Meanwhile, as illustrated in FIG. 6, an outer side of the bipolar cell 100 is provided with a case type pouch 130, and one end of the pouch 130 allows the anode terminal 111 and the cathode terminal 121 to be exposed to the outside and the other end of the pouch 130 allows a portion of the sealing part 220 and the connector 230 of the voltage monitoring terminal part to be exposed to the outside to enable the bipolar cell to be connected to the battery management system in order to measure the voltage or sort the defect.

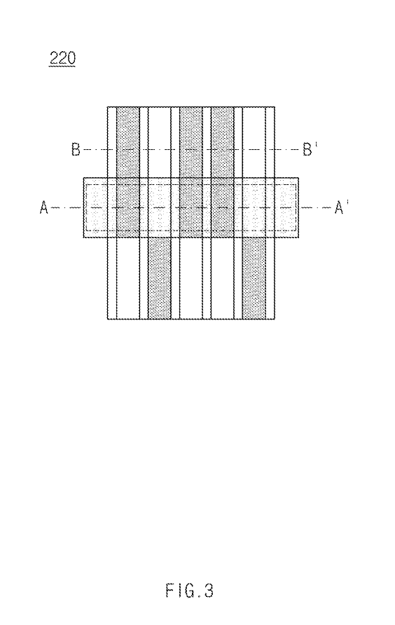

In addition, the sealing part 220 includes an outer layer 221 heat-fused to the pouch 130, an intermediate layer 222 formed at an inner side of the outer layer 221 to maintain a shape of the sealing part 220 and inhibit an electrical short-circuit at the time of heat-fusion to the pouch 130, and an inner layer 223 formed at an inner side of the intermediate layer 222 and connected to the flexible PCB 224 to thereby be fused, as illustrated in FIGS. 3 to 5.

Here, the outer layer 221 may be melted and fused at a low melting point between 130° C. and 140° C. to thereby be heat-fused to the pouch 130, the intermediate layer 222 may be melted and fused at a high melting point between 164° C. and 166° C. to maintain the shape of the sealing part 220 and inhibit the electrical short-circuit with the pouch 130 at the time of heat-fusion to the pouch 130, and the inner layer 223 may be melted and fused at a low melting point between 130° C. and 140° C. to be attached well to a metal, thereby securing a sealing property.

In one form the sealing part 220 is made of polyethylene (PE) or polyimide (PI) and the flexible PCB 224 formed in the sealing part 220 is made of copper (Cu), nickel (Ni), or aluminum (Al) to improve heat fusion and inner sealing properties.

As described above, the battery module having a bipolar cell according to one form of the present disclosure includes the bipolar cell 100 including the plurality of anode plates 110 and cathode plates 120 alternately stacked and connected to each other in series, the respective anode plates 110 having the anode terminals 111 formed at one ends thereof and having the measuring terminals 101 formed at the other ends thereof and measuring the voltage, and the respective cathode plates 120 having the cathode terminals 121 formed at one ends thereof and having the measuring terminals 101 formed at the other ends thereof and measuring the voltage, such that the stair-shaped steps are formed in the plurality of anode terminals 111, cathode terminals 121, and measuring terminals 101; the voltage monitoring terminal part including the coupled part 210 having the stair-shaped steps formed in the plurality of terminal connecting parts 201 so as to correspond to the measuring terminals 101 to have the measuring terminals 101 inserted therein, the sealing part 220 connected to the coupled part 210, provided with the flexible PCB 224, and sealing the flexible PCB 224 from the external environment, and the connector 230 having one end connected to the flexible PCB 224 of the sealing part 220 and the other end at which the coupling terminal is formed to measure the voltage of the bipolar cell 100 or sort the defect of the bipolar cell 100 at the time of being coupled to the battery management system; and the case type pouch 130 provided at the outer side of the bipolar cell 100 and having one end allowing the anode terminal 111 and the cathode terminal 121 to be exposed to the outside and the other end allowing a portion of the sealing part 220 and the connector 230 of the voltage monitoring terminal part to be exposed to the outside. Therefore, the voltage of the bipolar cell 100 is measured in a process of manufacturing a battery to improve defect sorting performance and easily sense whether or not the cell in use is abnormal, thereby making it possible to improve marketability and durability and safety of the battery.

Hereinabove, although the present disclosure has been described with reference to various forms and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A battery module having a bipolar cell, comprising:
a bipolar cell including a plurality of anode plates and cathode plates alternately stacked and connected to each other in series, the respective anode plates having anode terminals formed at ends thereof and having measuring terminals formed at other ends thereof for measuring a voltage and the respective cathode plates having cathode terminals formed at ends thereof and having measuring terminals formed at other ends thereof for measuring a voltage, such that steps are formed in a plurality of anode terminals, cathode terminals, and measuring terminals; and
a voltage monitoring terminal part having steps formed in a plurality of terminal connecting parts so as to correspond to the measuring terminals to allow the measuring terminals to be inserted therein, thereby measuring a voltage of the bipolar cell.

2. The battery module having a bipolar cell according to claim 1, wherein the steps of the measuring terminals and the steps of the terminal connecting parts have a stair shape in which the steps become high toward one end.

3. The battery module having a bipolar cell according to claim 1, wherein the voltage monitoring terminal part includes:
a coupled part having the terminal connecting parts formed therein to have the measuring terminals inserted therein;
a sealing part connected to the coupled part, provided with a flexible printed circuit board (PCB), and sealing the flexible PCB from an external environment, and
a connector having one end connected to the flexible PCB of the sealing part and the other end at which a coupling terminal is formed to measure the voltage of the bipolar cell or sort a defect of the bipolar cell at the time of being coupled to a battery management system (BMS).

4. The battery module having a bipolar cell according to claim 3, further comprising a case type pouch provided at an outer side of the bipolar cell and having one end allowing the anode terminal and the cathode terminal to be exposed to the outside and the other end allowing a portion of the sealing part and the connector of the voltage monitoring terminal part to be exposed to the outside.

5. The battery module having a bipolar cell according to claim 4, wherein the sealing part includes:
an outer layer heat-fused to the pouch;
an intermediate layer formed at an inner side of the outer layer to maintain a shape of the sealing part and inhibit an electrical short-circuit at the time of heat-fusion to the pouch; and
an inner layer formed at an inner side of the intermediate layer and connected to the flexible PCB to thereby be fused.

6. The battery module having a bipolar cell according to claim 5, wherein the outer layer and the inner layer are melted and fused at a low melting point between 130° C. and 140° C., and the intermediate layer is melted and fused at a high melting point between 164° C. and 166° C.

7. The battery module having a bipolar cell according to claim 3, wherein the coupled part in which the terminal connecting parts are formed is coupled to the measuring terminals of the bipolar cell through welding, soldering, or riveting.

8. The battery module having a bipolar cell according to claim 3, wherein the sealing part is made of a material selected from the group consisting of polyethylene (PE) or polyimide (PI) and the flexible PCB formed in the sealing part is made of copper (Cu), nickel (Ni), and aluminum (Al).

9. A battery module having a bipolar cell, comprising:
a bipolar cell including a plurality of anode plates and cathode plates alternately stacked and connected to each other in series, the respective anode plates having anode terminals formed at ends thereof and having measuring terminals formed at other ends thereof for measuring a voltage and the respective cathode plates having cathode terminals formed at ends thereof and having measuring terminals formed at other ends thereof for measuring a voltage, such that stair-shaped steps are formed in a plurality of anode terminals, cathode terminals, and measuring terminals;
a voltage monitoring terminal part including a coupled part having stair-shaped steps formed in a plurality of terminal connecting parts so as to correspond to the measuring terminals to have the measuring terminals inserted therein, a sealing part connected to the coupled part, provided with a flexible PCB, and sealing the flexible PCB from an external environment, and a connector having one end connected to the flexible PCB of the sealing part and the other end at which a coupling terminal is formed to measure a voltage of the bipolar cell or sort a defect of the bipolar cell at the time of being coupled to a BMS; and
a case type pouch provided at an outer side of the bipolar cell and having one end allowing the anode terminal and the cathode terminal to be exposed to the outside and the other end allowing a portion of the sealing part and the connector of the voltage monitoring terminal part to be exposed to the outside.

10. The battery module having a bipolar cell according to claim 9, wherein the sealing part includes:
an outer layer heat-fused to the pouch;
an intermediate layer formed at an inner side of the outer layer to maintain a shape of the sealing part and inhibit an electrical short-circuit at the time of heat-fusion to the pouch; and
an inner layer formed at an inner side of the intermediate layer and connected to the flexible PCB to thereby be fused.
